(19) United States
(12) Patent Application Publication
(10) Pub. No.: US 2022/0345580 A1
(43) Pub. Date: Oct. 27, 2022

(54) POWER CONTROL OF FAN DRIVER OF IMAGE FORMING APPARATUS BASED ON PWM CONTROL SIGNAL

(71) Applicant: Hewlett-Packard Development Company, L.P., Spring, TX (US)

(72) Inventors: Jun Young LEE, Seongnam-si (KR); Young Jun CHOI, Seongnam-si (KR); Byung Kwon LEE, Seongnam-si (KR)

(21) Appl. No.: 17/541,820

(22) Filed: Dec. 3, 2021

(30) Foreign Application Priority Data
Apr. 23, 2021 (KR) 10-2021-0052811

(51) Int. Cl. H04N 1/00; H03K 7/08; H02P 29/00

(52) U.S. Cl. CPC H04N 1/00904; H03K 7/08; H04N 1/00981; H02P 29/00; H04N 2201/0094

(57) ABSTRACT

An example image forming apparatus includes a fan, a fan driver to drive the fan, a switching controller, and a processor to output a pulse width modulated (PWM) control signal to control the fan driver. The switching controller may include a smoothing circuit to receive the PWM control signal output from the processor and convert the PWM control signal to a direct current signal, a comparator to compare a value of the direct current signal with a reference value and output a switch control signal, and a switch to provide power to the fan driver based on the switch control signal output from the comparator.

### BACKGROUND

An image forming apparatus may refer to an apparatus which prints print data generated in a terminal apparatus such as a computer on a printing medium such as paper. Examples of the image forming apparatus may include a copier, a printer, a facsimile, a scanner, a multi-function peripheral (MFP) which implements in combination the functions of the copier, the printer, the facsimile, and the scanner through an apparatus, and the like.

### BRIEF DESCRIPTION OF THE DRAWINGS

FIG. 1 is a diagram illustrating an image forming apparatus according to an example;

FIG. 2A is a diagram illustrating an image forming apparatus in which a fan driver is provided with a control board according to an example;

FIG. 2B is a diagram illustrating an image forming apparatus in which a fan driver is provided with a fan according to an example;

FIG. 3 is a diagram illustrating a switching controller according to an example;

FIG. 4 is a diagram illustrating a power control circuit of a fan driver according to an example;

FIG. 5 is a diagram illustrating an image forming apparatus which includes a sensor according to an example;

FIG. 6 is a diagram illustrating a flowchart of a power control method of an image forming apparatus according to an example; and

FIG. 7 is a diagram illustrating instructions stored in a computer readable recording medium according to an example.

### DETAILED DESCRIPTION

Various examples will be described below with reference to the accompanying drawings. The examples described herein may be modified and implemented in various different forms.

When a component is indicated as being “connected” to another component, the description may include being ‘directly connected,’ but also include being ‘connected through another component therebetween.’ In addition, when a certain component is indicated as “including,” or “comprising” another component, this means that other components may be further included rather than excluding the other components, unless otherwise specified. Furthermore, each example may be independently implemented or operated, but each example may be combined and implemented or operated.

In the disclosure, the term “image forming job” may refer to any of various jobs (e.g., copy, print, scan, or fax) associated with an image such as forming an image or generating/storing/transmitting an image file, and the term “job” may refer to an image forming job, but also refer to any or all series of processes for performing the image forming job.

In addition, the term “print data” may refer to data which may be converted to a printable format in the printer. If the printer supports direct printing, the file itself may be print data.

In addition, the term “image forming apparatus” may refer to a device to print print data generated from a terminal device such as a computer on a recording medium such as paper. Examples of the image forming apparatus may include a copier, a printer, a facsimile, a scanner, a multi-function peripheral (MFP) which implements in combination the functions of the copier, the printer, the facsimile, and the scanner through one device, or the like.

Examples of the disclosure are provided to reduce power consumption without using an additional control port by using a control signal of a fan driver driving a fan to simultaneously control power being supplied to the fan driver.

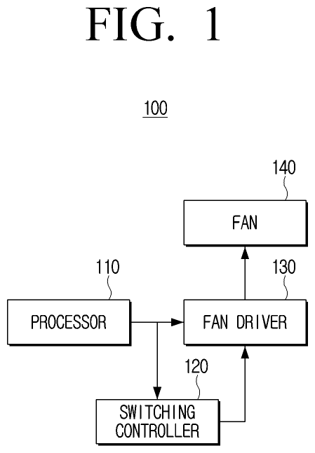

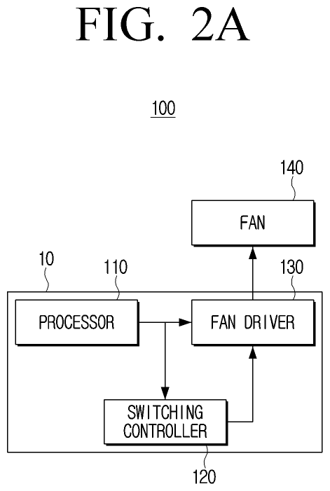

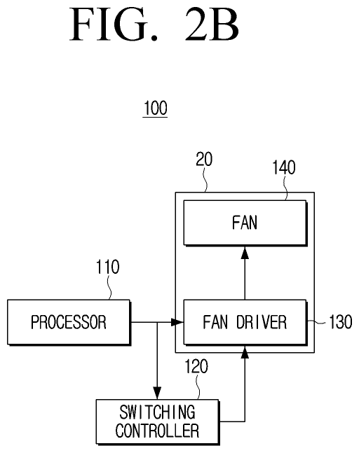

FIG. 1 is a diagram illustrating an image forming apparatus according to an example, FIG. 2A is a diagram illustrating an image forming apparatus in which a fan driver is provided with a control board according to an example, and FIG. 2B is a diagram illustrating an image forming apparatus in which a fan driver is provided with a fan according to an example. Examples of the disclosure will be described below with reference to FIGS. 1 to 2B.

Referring to FIG. 1, an image forming apparatus 100 may include a processor 110, a switching controller 120, a fan driver 130, and a fan 140.

The processor 110 may control an operation of the image forming apparatus 100. For example, the processor 110 may generate a print image and control an image forming engine (not shown) to print the generated print image on a printing medium such as paper. In addition, the processor 110 may control the switching controller 120 to supply power to or block power from the fan driver 130. The processor 110 may control an operation of the fan 140 through the fan driver 130. In an example, the processor 110 may output a pulse width modulation (PWM) control signal to the fan driver 130 to control the operation and a speed of the fan 140. Based on the processor 110 not outputting the PWM control signal, the fan driver 130 may not operate the fan. If the processor 110 outputs a duty ratio of the PWM control signal at 50%, the fan driver 130 may operate the fan 140 at a speed of 50% of a maximum speed. The switching controller 120 and the fan driver 130 may be connected with the same terminal of the processor 110. Accordingly, the PWM control signal output from the processor 110 may be simultaneously input to the switching controller 120 and the fan driver 130.

The switching controller 120 may control power that is provided to the fan driver 130. The switching controller 120 may be connected with a power supply device (not shown), the processor 110, and the fan driver 130. For example, an input terminal of the switching controller 120 may be connected with the power supply device and the processor 110, and an output terminal of the switching controller 120 may be connected with the fan driver 130. The switching controller 120 may block power from being provided to the fan driver 130 based on the PWM control signal input from the processor 110. Alternatively, the switching controller 120 may provide power provided from the power supply device to the fan driver 130. Example operations of the switching controller 120 will be described below.

The fan driver 130 may drive the fan 140 based on the power provided through the switching controller 120 and the PWM control signal input from the processor 110. An input terminal of the fan driver 130 may be connected with the processor 110 and the switching controller 120, and an output terminal may be connected with the fan 140. The fan driver 130 may be provided with power through the switching controller 120. Simultaneously, the fan driver 130 may receive the PWM control signal from the processor 110. Because the PMW control signal controls a power switching role of the switching controller 120 while simultaneously being input to the fan driver 130, the fan driver 130 may receive the power supply and the PWM control signal simultaneously (or, nearly simultaneously). In that case, the fan driver 130 may drive the fan 140 based on the PWM control signal. For example, based on the duty ratio of the PWM control signal being 25%, the fan driver 130 may output the voltage being output to the fan 140 at 25% of a maximum voltage, and the fan 140 may be driven at a speed of 25% of the maximum speed. As another example, based on the duty ratio of the PWM control signal being 100%, the fan driver 130 may output the voltage being output to the fan 140 at the maximum voltage, and the fan 140 may be driven at the maximum speed. Accordingly, the fan driver 130 may control a rotational speed of the fan 140 based on the PWM control signal.

The fan 140 may provide air to a heat source of the image forming apparatus 100 to reduce a temperature of the heat source. For example, the heat source may include the processor 110, the image forming engine, and the like.

In various examples, the fan driver 130 may be disposed at various positions. For example, the fan driver 130 may be implemented together with the processor 110 and the switching controller 120. As illustrated in FIG. 2A, the processor 110, the switching controller 120, and the fan driver 130 may be implemented on a control board 10. In an example, the control board 10 may be implemented as a printed circuit board (PCB). If the processor 110, the switching controller 120, and the fan driver 130 are included on the PCB of the control board 10, the processor 110, the switching controller 120, and the fan driver 130 may be connected using lines formed in the PCB of the control board 10. In that case, the fan driver 130 and the fan 140 may be connected through a separate connector.

Alternatively, the fan driver 130 may be implemented together with the fan 140. As illustrated in FIG. 2B, the fan driver 130 and the fan 140 may be provided as an integrated component 20. In this case, the fan driver 130 may be connected with the processor 110 and the switching controller 120 through a connector. The fan driver 130 may be disposed at various positions according to the size, form, structure, component, or the like of the image forming apparatus 100.

An example of the switching controller 120 and an example operation of the switching controller 120 will be described in below.

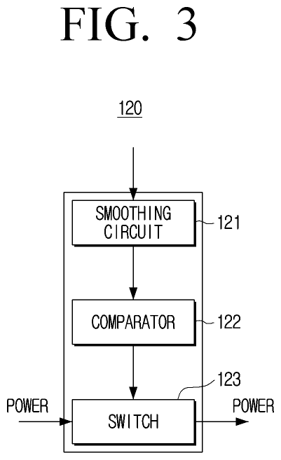

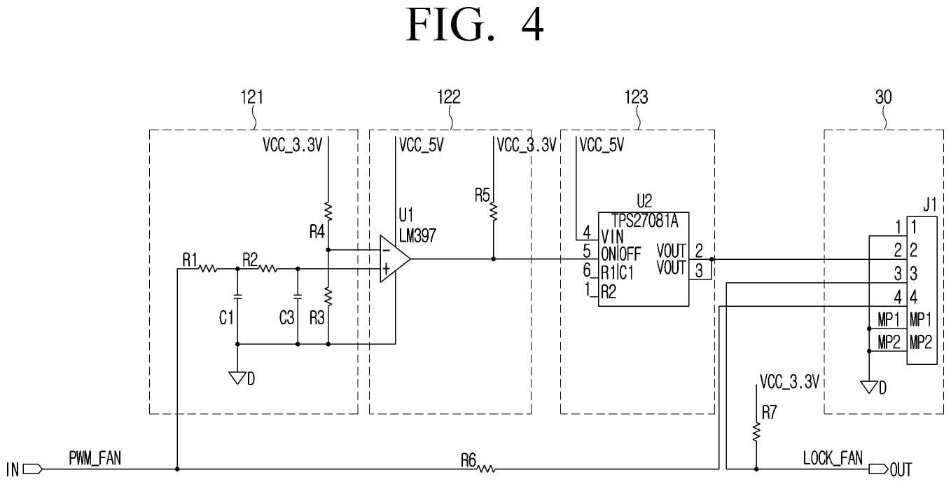

FIG. 3 is a diagram illustrating a switching controller according to an example, and FIG. 4 is a diagram illustrating a power control circuit of a fan driver according to an example.

Referring to FIG. 3, the switching controller 120 may include a smoothing circuit 121, a comparator 122, and a switch 123.

An input terminal of the smoothing circuit 121 may be connected with an output terminal (e.g., a PWM control signal output terminal) of the processor 110, and an output terminal of the smoothing circuit 121 may be connected with an input terminal of the comparator 122. The input terminal of the comparator 122 may be connected with the output terminal of the smoothing circuit 121, and an output terminal of the comparator 122 may be connected with an input terminal of the switch 123. The input terminal of the switch 123 may be connected with an output terminal of the power supply device and the output terminal of the comparator 122, and an output terminal of the switch 123 may be connected with an input terminal of the fan driver 130.

The smoothing circuit 121 may convert the PWM control signal received from the processor 110 to a direct current signal. In an example, the PWM control signal of which the duty ratio is set may be a type of alternating current signal. The comparator 122 may receive the direct current signal from the smoothing circuit 121. Accordingly, the smoothing circuit 121 may convert the input PWM control signal (i.e., an alternating current signal) to the direct current signal for inputting to the comparator 122.

The comparator 122 may compare a value of the direct current signal converted in the smoothing circuit 121 with a reference value and output a switch control signal. The switch control signal, which is output from the comparator 122, may be an on signal or off signal.

The switch 123 may provide power to the fan driver 130 based on the switch control signal. For example, based on the switch control signal, which is output from the comparator 122, being an on signal, the switch 123 may provide power to the fan driver 130, and based on the switch control signal, which is output from the comparator 122, being an off signal, the switch 123 may block power from being provided to the fan driver 130.

For example, based on a magnitude of the PWM control signal being 5V and the duty ratio being 10%, 10% of one cycle of the PWM control signal may be 5V. The PWM control signal of which the duty ratio is 10% may be input to the smoothing circuit 121. The smoothing circuit 121 may convert the PWM control signal to the direct current signal. Because the magnitude of the PWM control signal is 5V and the duty ratio is 10%, the switch control signal output from the smoothing circuit 121 may be a direct current signal of 0.5V.

The comparator 122 may compare the value of the converted direct current signal and a reference value. If the fan 140 is designed so as to not be driven based on the PWM control signal of a 10% duty ratio, the reference value may be set to 1V. In the example described above, because the value of the direct current signal input to the comparator 122 is 0.5V which is smaller than the reference value of 1V, the comparator 122 may output the off signal (or, low signal) to the switch 123. The switch 123 may block power from being provided to the fan driver 130 based on the off signal input from the comparator 122.

Based on the fan 140 being designed so as to be driven based on the PWM control signal of a 10% duty ratio, the reference value may be set to 0.3V. In the above-described example, because the value of the direct current signal input to the comparator 122 is 0.5V which is greater than the reference value of 0.3V, the comparator 122 may output the on signal (or, high signal) to the switch 123. The switch 123 may provide power to the fan driver 130 based on the on signal input from the comparator 122. As described above, the PWM control signal output terminal of the processor 110 may be connected with the input terminal of the switching controller 120 (or, smoothing circuit 121) and the input terminal of the fan driver 130. Further, a power input terminal of the fan driver 130 may be connected with a power output terminal of the switching controller 120 (or, switch 123). Accordingly, based on the power being supplied to the fan driver 130, the fan driver 130 may also receive the PWM control signal of which the duty ratio is 10% from the processor 110. The fan driver 130 may output a voltage of 10% of the maximum voltage to the fan 140 based on the PWM control signal of which the duty ratio is 10%. The fan 140 may be driven at the speed of 10% of the maximum speed.

In the above-described example, based on the duty ratio of the PWM control signal becoming greater, the value of the direct current signal input to the comparator 122 may also become greater. Because the reference value of the comparator 122 is the same, even if the value of the direct current signal which is input becomes greater, the switch 123 may maintain the output of the on signal. Accordingly, the fan driver 130 may continue receiving power, and control the magnitude of the voltage provided to the fan 140 based on the duty ratio of the PWM control signal which is input from the processor 110. The speed of the fan 140 may be adjusted according to the magnitude of the voltage input from the fan driver 130.

Referring to FIG. 4, the power control circuit of the fan driver 130 according to an example is disclosed. As illustrated in FIG. 4, based on the fan driver 130 and the fan 140 being integrally implemented, the switch 123 and the fan driver 130 may be connected through a connector 30.

Examples of the disclosure reduce standby power by blocking the power provided to the fan driver in the event that the fan 140 is not driven. In addition, the input signal of the switching controller 120 which controls the power supply may be the PWM control signal which is input to the fan driver 130. Accordingly, examples of the disclosure control the power provided to the fan driver 130 without changing firmware or other machine readable instructions and using a separate input output terminal of the processor 110. In addition, because the reference value of the comparator 122 may be adjusted, it may be applicable to a variety of image forming apparatuses.

In an example, the duty ratio of the PWM control signal which is output from the processor 110 may be controlled according to a temperature of the heat source, or the like.

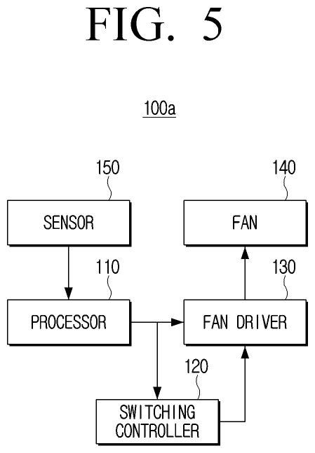

FIG. 5 is a diagram illustrating an image forming apparatus which includes a sensor according to an example.

Referring to FIG. 5, an image forming apparatus 100a may include the processor 110, the switching controller 120, the fan driver 130, the fan 140, and a sensor 150. Because the switching controller 120, the fan driver 130, and the fan 140 are the same as described above, a repetitive description will be omitted here.

The sensor 150 may detect a temperature of a heat source. For example, the sensor 150 may include a thermometer, a heat detection sensor, an infrared sensor, and the like. The heat source may be the processor 110. Based on the heat source being the processor 110, the sensor 150 may be provided with the processor 110 or disposed in an area adjacent to or otherwise near the processor 110. Alternatively, based on the heat source being the image forming engine, the sensor 150 may be disposed in an area adjacent to or near the image forming engine.

The processor 110 may receive temperature data detected from the sensor 150. The processor 110 may control a duty ratio of a PWM control signal based on the input temperature data. For example, the image forming apparatus 100a may further include a memory (not shown). The memory may store an instruction on the image forming apparatus 100a. For example, the memory may be stored with various programs (e.g., machine readable instructions) for the image forming apparatus 100a to operate according to the various examples of the disclosure. In addition, the memory may store data on the duty ratio of the PWM control signal according to temperature. The processor 110 may output the PWM control signal based on the temperature data input from the sensor 150 and the duty ratio corresponding to the temperature data.

In an example, the image forming apparatus 100a may not include the sensor 150. In this case, the image forming apparatus 100a may store data on an expected amount of thermal energy according to an operational status. The image forming apparatus 100a may control the duty ratio of the PWM control signal according to an operational status and the corresponding data on the amount of thermal energy. For example, the image forming apparatus 100a may store data such as a duty ratio of 50% for operation A, a duty ratio of 30% for operation B, a duty ratio of 70% for operation C, and the like. Based on the image forming apparatus 100a performing operation A, the processor 110 may output the PWM control signal at the duty ratio of 50% based on the stored data. Alternatively, based on the image forming apparatus 100a performing operation C, the processor 110 may output the PWM control signal at the duty ratio of 70% based on the stored data.

Various examples of circuits to control an operation of the fan 140 with the PWM control signal have been described above. Below, an example power control method will be described.

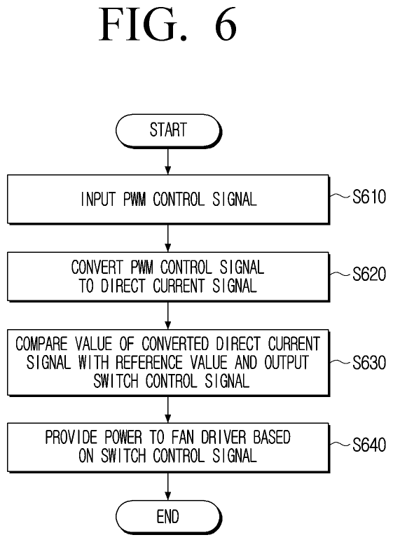

FIG. 6 is a diagram illustrating a flowchart of a power control method of an image forming apparatus according to an example.

Referring to FIG. 6, an image forming apparatus may receive a PWM control signal in operation S610. A switching controller of the image forming apparatus may receive the PWM control signal output from a processor. The switching controller of the image forming apparatus may include a smoothing circuit, a comparator, and a switch. The PWM control signal input to the switching controller may be input to the smoothing circuit. The image forming apparatus may convert the PWM control signal to a direct current signal in operation S620. The smoothing circuit of the switching controller may convert the input PWM control signal to the direct current signal.

The image forming apparatus may compare a value of the converted direct current signal with a reference value and output a switch control signal in operation S630. The comparator of the switching controller may compare the value of the direct current signal with the reference value and output the switch control signal. For example, based on the value of the converted direct current signal being less than or equal to the reference value, a low signal which turns-off the switch may be output. Alternatively, the comparator may, based on the value of the converted direct current signal exceeding the reference value, output a high signal which turns-on the switch.

The image forming apparatus may provide power to a fan driver based on the switch control signal in operation S640. For example, based on the switch of the switching controller receiving the low signal from the comparator, the switch may block power from being provided to the fan driver based on the low signal. Alternatively, based on the switch of the switching controller receiving the high signal from the comparator, the switch may provide power to the fan driver based on the high signal.

In an example, the image forming apparatus may further include a sensor. Based on the image forming apparatus including the sensor, the sensor of the image forming apparatus may detect a temperature of a heat source. In that case, the processor may receive the temperature data detected from the sensor. The processor may output by controlling the duty ratio of the PWM control signal based on the input temperature data. For example, the processor may control the duty ratio of the PWM control signal to be proportionate to the input temperature data.

In another example, based on the image forming apparatus not including the sensor, the image forming apparatus may store data on the expected amount of thermal energy according to an operational status. The image forming apparatus may control the duty ratio of the PWM control signal according to an algorithm set based on the operational status and the stored data on the amount of thermal energy.

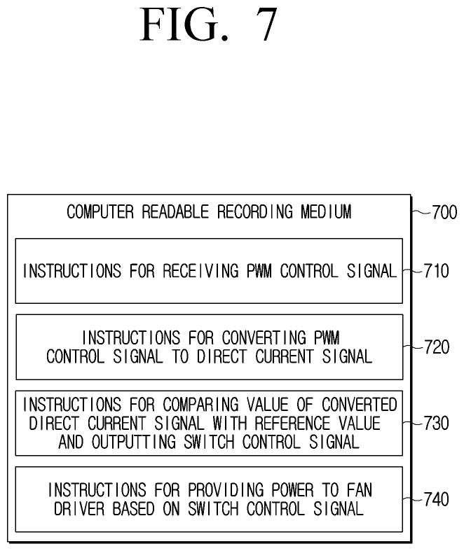

FIG. 7 is a diagram illustrating instructions stored in a computer readable recording medium according to an example.

Referring to FIG. 7, an example power control process executed in an image forming apparatus as described above may be implemented in the form of a computer or a computer readable recording medium which stores instructions or data executable by a processor. A computer readable recording medium 700 may store instructions associated with an operation of an image forming apparatus as described above. For example, the computer readable recording medium 700 may include instructions for receiving a PWM control signal 710, instructions for converting the PWM control signal to a direct current signal 720, instructions for comparing a value of the converted direct current signal with a reference value and outputting a switch control signal 730, and instructions for providing power to a fan driver based on the switch control signal 740.

In various examples, the computer readable recording medium may include a read-only memory (ROM), a random-access memory (RAM), a flash memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-Res, a magnetic tape, a floppy disk, a magneto-optical data storage device, an optical data storage device, a hard disk, a solid-state drive (SSD), and may store instructions or software, related data, data files, and data structures, and the computer readable recording medium may be any device capable of providing instructions or software, related data, data files, and data structures to the processor or the computer so that the processor or the computer may execute an instruction.

Examples of the disclosure have been illustrated and described. However, the disclosure is not limited to the above-described examples, and various changes in form and details may be made without departing from the spirit and scope as defined, by the following claims and their equivalents.

What is claimed is:

1. An image forming apparatus, comprising:
a fan;
a fan driver to drive the fan;
a switching controller; and
a processor to output a pulse width modulated (PWM) control signal to control the fan driver,
wherein the switching controller comprises:
a smoothing circuit to receive the PWM control signal output from the processor and convert the PWM control signal to a direct current signal;
a comparator to compare a value of the direct current signal with a reference value and output a switch control signal; and
a switch to provide power to the fan driver based on the switch control signal output from the comparator.

2. The image forming apparatus of claim 1,
wherein an output terminal of the processor which outputs the PWM control signal is connected with an input terminal of the fan driver and an input terminal of the smoothing circuit,
wherein an input terminal of the comparator is connected to an output terminal of the smoothing circuit which outputs the direct current signal, and an output terminal of the comparator is connected to a control terminal of the switch, and
wherein the switch is connected with an output terminal of a power device and an input terminal of the fan driver.

3. The image forming apparatus of claim 1,
wherein the comparator is to output, based on a value of the direct current signal being less than or equal to the reference value, a low signal turning-off the switch, and
wherein the switch is to block the power from being provided to the fan driver based on the output low signal.

4. The image forming apparatus of claim 1,
wherein the comparator is to output, based on a value of the direct current signal exceeding the reference value, a high signal turning-off the switch, and
wherein the switch is to provide the power to the fan driver based on the output high signal.

5. The image forming apparatus of claim 3, wherein the fan driver is to drive the fan based on the power provided through the switch and the PWM control signal.

6. The image forming apparatus of claim 1, further comprising:
a sensor to detect a temperature of a heat source,
wherein the processor is to receive temperature data detected from the sensor and control a duty ratio of the PWM control signal based on the temperature data.

7. The image forming apparatus of claim 6, wherein the processor is to control the duty ratio of the PWM control signal to be proportionate to the temperature data.

8. The image forming apparatus of claim 6, wherein the fan driver is to control a voltage output to the fan to be proportionate to the duty ratio of the PWM control signal.

9. The image forming apparatus of claim 6, wherein the heat source comprises the processor.

10. The image forming apparatus of claim 1, wherein the fan driver is provided integrally with the fan.

11. A power control method of an image forming apparatus, the method comprising:
receiving, by a switching controller, a pulse width modulated (PWM) control signal output from a processor;
converting the PWM control signal to a direct current signal;
comparing a value of the direct current signal with a reference value and outputting a switch control signal; and
providing power to a fan driver based on the switch control signal.

12. The method of claim 11, wherein the outputting the switch control signal comprises outputting, based on a value of the direct current signal being less than or equal to the reference value, a low signal which turns-off the switch, and blocking the power from being provided to the fan driver based on the output low signal.

13. The method of claim 11, wherein the outputting the switch control signal comprises outputting, based on a value of the direct current signal exceeding the reference value, a high signal which turns-on the switch, and providing the power to the fan driver based on the output high signal.

14. The method of claim 11, further comprising:
detecting a temperature of a heat source;
receiving, by the processor, detected temperature data; and
controlling a duty ratio of the PWM control signal based on the temperature data.

15. The method of claim 14, wherein the controlling of the duty ratio of the PWM control signal comprises controlling a duty ratio of the PWM control signal to be proportionate to input temperature data.
